(19) United States
(12) Patent Application Publication
(10) Pub. No.: US 2016/0069954 A1
(43) Pub. Date: Mar. 10, 2016

(54) SEMICONDUCTOR APPARATUS

(71) Applicant: SK hynix Inc., Icheon-si (KR)

(72) Inventor: In Jun MOON, Icheon-si (KR)

(21) Appl. No.: 14/572,929

(22) Filed: Dec. 17, 2014

(30) Foreign Application Priority Data
Sep. 5, 2014 (KR) 10-2014-0118836

(51) Int. Cl. G01R 31/3177

(52) U.S. Cl. CPC G01R 31/3177

(57) ABSTRACT

A semiconductor apparatus may include a first normal circuit configured to generate a normal signal while operating in a normal operation, and a test signal generation unit configured to generate a test signal in response to a test control signal. The semiconductor apparatus may include a signal transfer unit configured to transfer one of either the normal signal or the test signal, as an internal signal, to a signal line, and a second normal circuit configured to perform the normal operation in response to receiving the internal signal from the signal line. The semiconductor apparatus may include a test operation circuit configured to perform a test operation in response to receiving the internal signal from the signal line.

### CROSS-REFERENCES TO RELATED APPLICATION

The present application claims priority under 35 U.S.C. §119(a) to Korean application number 10-2014-0118836, filed on Sep. 5, 2014, in the Korean Intellectual Property Office, which is incorporated herein by reference in its entirety.

### BACKGROUND

1. Technical Field

Various embodiments generally relate to a semiconductor integrated circuit, and more particularly, to a semiconductor apparatus.

2. Related Art

A semiconductor apparatus may perform a test operation to determine whether or not a fail has occurred. Only a product which is determined to be normal may be commercialized.

As a semiconductor apparatus is designed to perform a number of operations, the semiconductor apparatus is also designed to perform a larger number of tests.

As the number of tests of a semiconductor apparatus increases, an increased number of test circuits are designed and configured in the semiconductor apparatus.

The semiconductor apparatus includes a number of test circuits, and a number of signal lines are formed in the semiconductor apparatus to be used for operating the test circuits. These signal lines increase the area used by the semiconductor apparatus.

When considering that a semiconductor apparatus trends toward miniaturization, an increase in an area due to signals lines used for a test serves may act as an obstacle to the miniaturization of the semiconductor apparatus.

### SUMMARY

In an embodiment, a semiconductor apparatus may include a first normal circuit configured to generate a normal signal while operating in a normal operation, and a test signal generation unit configured to generate a test signal in response to a test control signal. The semiconductor apparatus may include a signal transfer unit configured to transfer one of either the normal signal or the test signal, as an internal signal, to a signal line. The semiconductor apparatus may include a second normal circuit configured to perform the normal operation in response to receiving the internal signal from the signal line, and a test operation circuit configured to perform a test operation in response to receiving the internal signal from the signal line.

In an embodiment, a semiconductor apparatus may include a first normal circuit configured to generate a first normal signal while operating in a normal operation, and a second normal circuit configured to generate a second normal signal while operating in the normal operation. The semiconductor apparatus may include a test signal generation unit configured to generate a first test signal and a second test signal in response to a test control signal. The semiconductor apparatus may include a first signal transfer unit configured to transfer one of either the first normal signal or the first test signal, as a first internal signal, to a first signal line. The semiconductor apparatus may include a second signal transfer unit configured to transfer one of either the second normal signal or the second test signal, as a second internal signal, to a second signal line. The semiconductor apparatus may include a third normal circuit configured to perform the normal operation in response to receiving the first internal signal from the first signal line, and a fourth normal circuit configured to perform the normal operation in response to receiving the second internal signal from the second signal line. The semiconductor apparatus may include a first test operation circuit configured to perform a test operation in response to receiving the first internal signal from the first signal line, and a second test operation circuit configured to perform the test operation in response to receiving the second internal signal from the second signal line.

In an embodiment, a semiconductor apparatus may include a normal circuit, a signal transfer unit coupled to the normal circuit through a signal line, and a test operation circuit coupled to the signal line. The signal transfer unit is configured to output an internal signal to the signal line in response to receiving a test signal or a normal signal.

In an embodiment, a semiconductor apparatus may include a first normal circuit, a signal transfer unit electrically coupled between the first normal circuit and a signal line, and a test signal generation unit coupled to the signal transfer unit. The signal transfer unit is configured to output test signals to the signal line in a test mode, and output normal signals, using the same signal line used by the test signals, while the semiconductor apparatus operates in a normal operation.

### BRIEF DESCRIPTION OF THE DRAWINGS

FIG. 1 is a configuration diagram illustrating a representation of an example of a semiconductor apparatus in accordance with an embodiment.

FIG. 2 is a configuration diagram illustrating a representation of an example of the test signal generation unit illustrated in FIG. 1.

FIG. 3 is a configuration diagram illustrating a representation of an example of a semiconductor apparatus in accordance with an embodiment.

FIG. 4 illustrates a block diagram of an example of a representation of a system employing the semiconductor apparatus in accordance with the embodiments discussed above with relation to FIGS. 1-3.

### DETAILED DESCRIPTION

Hereinafter, a semiconductor apparatus will be described below with reference to the accompanying drawings through various examples of embodiments.

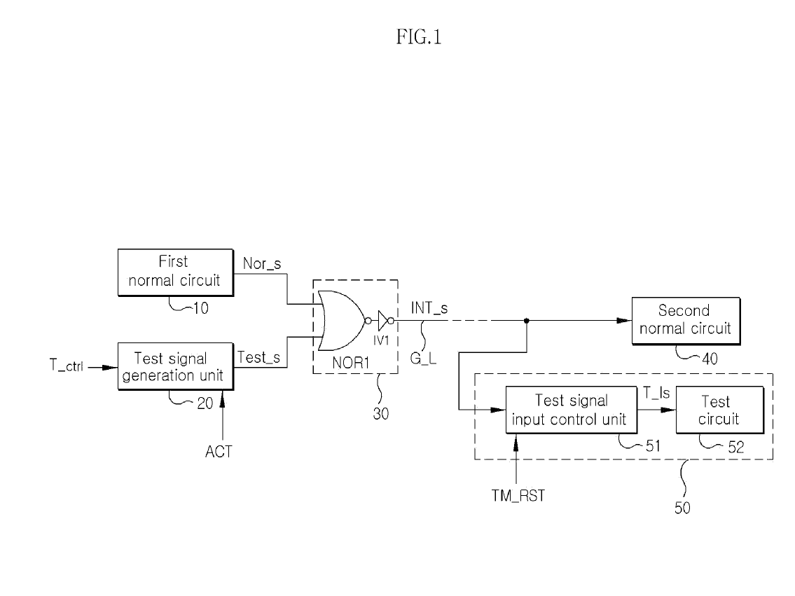

Referring to FIG. 1, a semiconductor apparatus in accordance with an embodiment may include a first normal circuit 10, a test signal generation unit 20, and a signal transfer unit 30. The semiconductor apparatus may include a second normal circuit 40, and a test operation circuit 50.

The first normal circuit 10 may generate a normal signal Nor_s while operating in a normal operation.

The test signal generation unit 20 may generate a test signal Test_s in response to a test control signal T_ctrl. For example, the test signal generation unit 20 may include a decoder. The decoder decodes the test control signal T_ctrl and generates the test signal Test_s. The test signal generation unit 20 may include a register for outputting a preset test signal Test_s in response to the test control signal T_ctrl. The test signal generation unit 20 may disable the test signal Test_s in response to a signal ACT. The signal ACT commands the normal operation. The signal ACT which commands the normal operation may be an active signal which commands the normal operation of a memory.

The signal transfer unit 30 may transfer the normal signal Nor_s or the test signal Test_s, as an internal signal INT_s, to a signal line G_L. The signal line G_L may be a signal line for transferring the internal signal INT_s between the first normal circuit 10 and the second normal circuit 40. For example, the signal transfer unit 30 enables the internal signal INT_s and transfers the enabled internal signal INT_s to the signal line G_L when even one of either the normal signal Nor_s or the test signal Test_s is enabled.

The signal transfer unit 30 may include a NOR gate NOR1 and an inverter IV1. The NOR gate NOR1 may be inputted with the normal signal Nor_s and the test signal Test_s. The inverter IV1 may be inputted with the output signal of the NOR gate NOR1, and may output the internal signal INT_s to the signal line G_L.

The second normal circuit 40 may perform the normal operation in response to the internal signal INT_s which is transferred from the signal line G_L.

The test operation circuit 50 may perform a test operation in response to the internal signal INT_s transferred from the signal line G_L. For example, the test operation circuit 50 may perform the test operation in response to the internal signal INT_s, and may interrupt the test operation when a test initialization signal TM_RST is enabled.

The test operation circuit 50 may include a test signal input control unit 51 and a test circuit 52.

The test signal input control unit 51 may latch the internal signal INT_s transferred from the signal line G_L, and may output a test latch signal T_ls. The test signal input control unit 51 may disable the test latch signal T_ls when the test initialization signal TM_RST is enabled. The test signal input control unit 51 may be configured to include an SR latch.

The test circuit 52 may perform the test operation when the test latch signal T_ls is, for example, enabled.

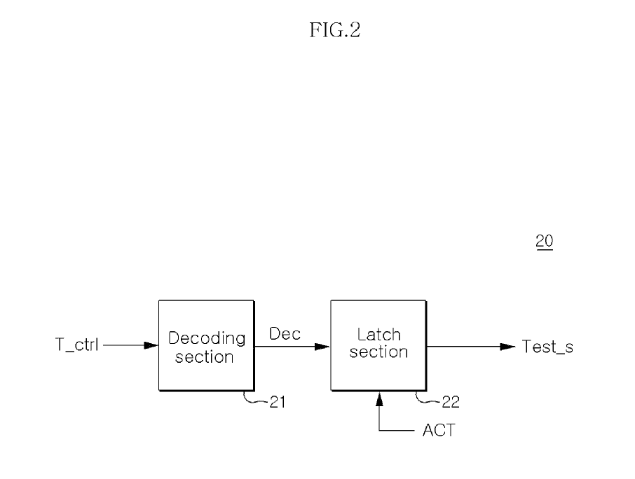

Referring to FIG. 2, the test signal generation unit 20 may include a decoding section 21 and a latch section 22.

The decoding section 21 may decode the test control signal T_ctrl and generate a decoding signal Dec.

The latch section 22 may latch the decoding signal Dec. The latch section 22 may output the test signal Test_s. The latch section 22 may disable the test signal Test_s in response to the signal ACT which commands the normal operation. The latch section 22 may be configured to include an SR latch.

The semiconductor apparatus in accordance with an embodiment, configured as mentioned above, may operate, for example, as follows. It may be assumed that the signal ACT which commands the normal operation is an active signal ACT.

In the normal operation, the normal signal Nor_s as the output signal of the first normal circuit 10 is transferred to the second normal circuit 40 through the signal transfer unit 30 and the signal line G_L. The test signal generation unit 20 may disable the test signal Test_s by the active signal ACT. The active signal ACT may be enabled in the normal operation. Therefore, since the signal transfer unit 30 is inputted with the test signal Test_s which is disabled, the signal transfer unit 30 may transfer the internal signal INT_s to the second normal circuit 40 through the signal line G_L in response to the normal signal Nor_s as the other input thereto.

Since the test operation circuit 50 disables the test latch signal T_ls in response to the test initialization signal TM_RST which is enabled, the test operation circuit 50 does not perform the test operation.

As a result, in the normal operation, the normal signal Nor_s outputted from the first normal circuit 10 is transferred to the second normal circuit 40.

In the test operation, the active signal ACT is disabled. Also, the test initialization signal TM_RST is disabled.

The test signal generation unit 20 decodes the test control signal T_ctrl which is inputted in a test, and generates the test signal Test_s. The normal signal Nor_s is disabled.

Since the signal transfer unit 30 is inputted with the normal signal Nor_s which is disabled, the signal transfer unit 30 outputs the internal signal INT_s to the signal line G_L in response to the test signal Test_s as the other input thereto.

The test signal input control unit 51 latches the internal signal INT_s transferred from the signal line G_L, and transfers the test latch signal T_ls to the test circuit 52. The test circuit 52 performs the test operation in response to the test latch signal T_ls. While performing the test operation, when it is necessary to interrupt the operation of the test circuit 52 to perform another test, the test initialization signal TM_RST may be enabled.

As is apparent from the above descriptions, in the semiconductor apparatus in accordance with an embodiment, since a test signal may be transferred using a signal line which transfers signals between normal circuits in a normal operation, a test may be performed without the need of adding a separate signal line for transferring a test signal in a test.

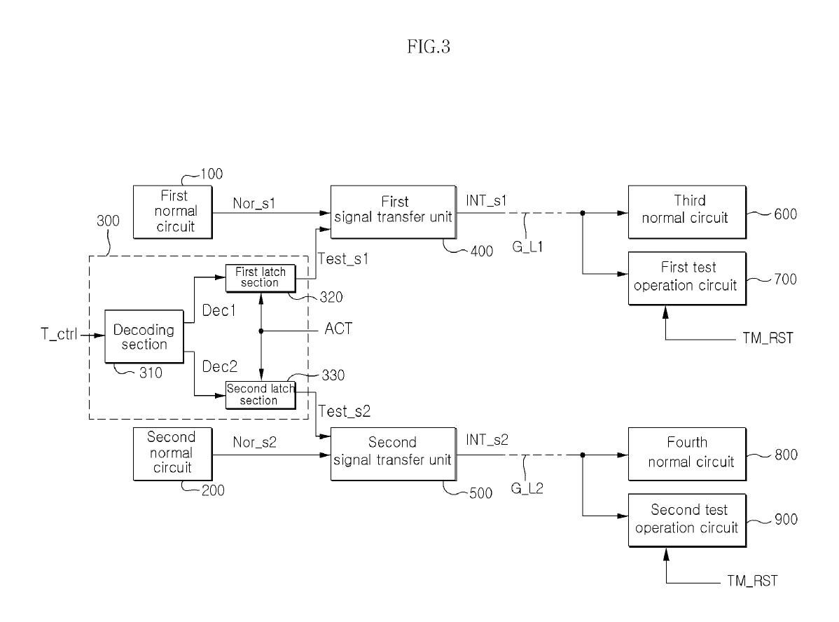

Referring to FIG. 3, a semiconductor apparatus in accordance with an embodiment may include a first normal circuit 100, a second normal circuit 200, and a test signal generation unit 300. The semiconductor apparatus may include a first signal transfer unit 400, a second signal transfer unit 500, and a third normal circuit 600. The semiconductor apparatus may include a first test operation circuit 700, a fourth normal circuit 800, and a second test operation circuit 900.

The first normal circuit 100 may generate a first normal signal Nor_s1 in a normal operation.

The second normal circuit 200 may generate a second normal signal Nor_s2 in the normal operation.

The test signal generation unit 300 may generate a first test signal Test_s1 and a second test signal Test_s2 in response to a test control signal T_ctrl.

The test signal generation unit 300 may include a decoding section 310, a first latch section 320, and a second latch section 330.

The decoding section 310 may decode the test control signal T_ctrl, and generate a first decoding signal Dec1. The decoding section 310 may decode the test control signal T_ctrl, and generate a second decoding signal Dec2.

The first latch section 320 may latch the first decoding signal Dec1. The first latch section 320 may output the first test signal Test_s1. The first latch section 320 may disable the first test signal Test_s1 in response to a signal ACT. The signal ACT may command the normal operation. For example, the first latch section 320 may disable the first test signal Test_s1 when the signal ACT, commanding for example the normal operation, is enabled.

The second latch section 330 may latch the second decoding signal Dec2, and may output the second test signal Test_s2. The second latch section 330 may disable the second test signal Test_s2 in response to the signal ACT. The signal ACT may command the normal operation. For example, the second latch section 330 may disable the second test signal Test_s2 when the signal AC, commanding for example the normal operation, is enabled. The first and second latch sections 320 and 330 may be configured to include SR latches.

The first signal transfer unit 400 may transfer the first normal signal Nor_s1 or the first test signal Test_s1, as a first internal signal INT_s1, to a first signal line G_L1. For example, the first signal transfer unit 400 may enable the first internal signal INT_s1 when, for example, one of either the first normal signal Nor_s1 or the first test signal Test_s1 is enabled.

The second signal transfer unit 500 may transfer the second normal signal Nor_s2 or the second test signal Test_s2, as a second internal signal INT_s2, to a second signal line G_L2. For example, the second signal transfer unit 500 enables the second internal signal INT_s2 when one of either the second normal signal Nor_s2 or the second test signal Test_s2 is enabled. Each of the first and second signal transfer units 400 and 500 may be configured to include a NOR gate and an inverter in the substantially the same manner as the signal transfer unit 30 illustrated in FIG. 1.

The third normal circuit 600 may perform the normal operation in response to the first internal signal INT_s1 transferred from the first signal line G_L1.

The first test operation circuit 700 may perform a test operation in response to the first internal signal INT_s1 transferred from the first signal line G_L1. The first test operation circuit 700 may interrupt the performance of the test operation when a test initialization signal TM_RST is, for example, enabled. The first test operation circuit 700 may be configured in substantially the same way as the test operation circuit 50 illustrated in FIG. 1 except that the signals inputted thereto and the signals outputted therefrom are different.

The fourth normal circuit 800 may perform the normal operation in response to the second internal signal INT_s2 transferred from the second signal line G_L2.

The second test operation circuit 900 may perform the test operation in response to the second internal signal INT_s2 transferred from the second signal line G_L2. The second test operation circuit 900 may interrupt the performance of the test operation when the test initialization signal TM_RST is, for example, enabled. The second test operation circuit 900 may be configured in substantially the same way as the test operation circuit 50 illustrated in FIG. 1 except that the signals inputted thereto and the signals outputted therefrom are different.

The semiconductor apparatus in accordance with an embodiment, configured as mentioned above, may operate, for example, as follows. It may be assumed, for example, that the signal ACT commanding the normal operation is an active signal ACT.

In the normal operation, the first and second normal signals Nor_s1 and Nor_s2 as the output signals of the first and second normal circuits 100 and 200 are respectively transferred to the third and fourth normal circuits 600 and 800 through the first and second signal transfer units 400 and 500 and the first and second signal lines G_L1 and G_L2. The test signal generation unit 300 may disable the first and second test signals Test_s1 and Test_s2 in response to the active signal ACT. The active signal ACT may be, for example, enabled in the normal operation. Therefore, since the first and second signal transfer units 400 and 500 are respectively inputted with the first and second test signals Test_s1 and Test_s2 which are disabled, the first and second signal transfer units 400 and 500 transfer the first and second internal signals INT_s1 and INT_s2 to the third and fourth normal circuits 600 and 800 through the first and second signal lines G_L1 and G_L2 in response to the first and second normal signals Nor_s1 and Nor_s2 as the other inputs thereto.

The first and second test operation circuits 700 and 800 do not perform the test operation in response to an enabled test initialization signal TM_RST.

As a result, in the normal operation, the first normal signal Nor_s1 outputted from the first normal circuit 100 is transferred to the third normal circuit 600. Further, the second normal signal Nor_s2 outputted from the second normal circuit 200 is transferred to the fourth normal circuit 800.

In the test operation, the active signal ACT is disabled. Also, the test initialization signal TM_RST is disabled.

The test signal generation unit 300 decodes the test control signal T_ctrl which is inputted in a test, and generates the first and second test signals Test_s1 and Test_s2. The first and second normal signals Nor_s1 and Nor_s2 are disabled.

Since the first and second signal transfer units 400 and 500 are inputted with the first and second normal signals Nor_s1 and Nor_s2 which are disabled, the first and second signal transfer units 400 and 500 output the first and second internal signals INT_s1 and INT_s2 to the first and second signal lines G_L1 and G_L2 in response to the first and second test signals Test_s1 and Test_s2 as the other inputs thereto.

The first and second test operation circuits 700 and 900 perform the test operation in response to the first and second internal signals INT_s1 and INT_s2 transferred through the first and second signal lines G_L1 and G_L2. While performing the test operation, when it is necessary to interrupt the operations of the first and second test operation circuits 700 and 900 to perform another test, the test initialization signal TM_RST may be enabled.

As is apparent from the above descriptions, in the semiconductor apparatus in accordance with an embodiment, since test signals may be transferred using signal lines which transfer signals between normal circuits in a normal operation, tests may be performed without the need of adding separate signal lines for transferring test signals in tests.

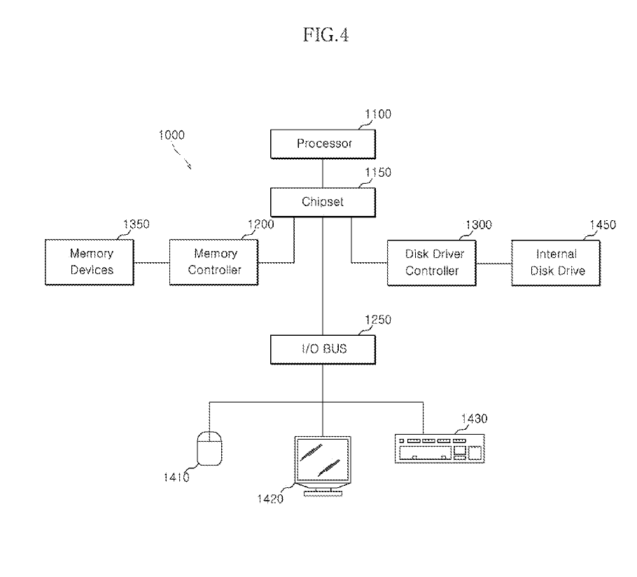

The semiconductor apparatuses discussed above (see FIGS. 1-3) are particular useful in the design of memory devices, processors, and computer systems. For example, referring to FIG. 4, a block diagram of a system employing the semiconductor apparatuses in accordance with the embodiments are illustrated and generally designated by a reference numeral 1000. The system 1000 may include one or more processors or central processing units (“CPUs”) 1100. The CPU 1100 may be used individually or in combination with other CPUs. While the CPU 1100 will be referred to primarily in the singular, it will be understood by those skilled in the art that a system with any number of physical or logical CPUs may be implemented.

A chipset 1150 may be operably coupled to the CPU 1100. The chipset 1150 is a communication pathway for signals between the CPU 1100 and other components of the system 1000, which may include a memory controller 1200, an input/output (“I/O”) bus 1250, and a disk drive controller 1300. Depending on the configuration of the system, any one of a number of different signals may be transmitted through the chipset 1150, and those skilled in the art will appreciate that the routing of the signals throughout the system 1000 can be readily adjusted without changing the underlying nature of the system.

As stated above, the memory controller 1200 may be operably coupled to the chipset 1150. The memory controller 1200 may include at least one semiconductor apparatus as discussed above with reference to FIGS. 1-3. Thus, the memory controller 1200 can receive a request provided from the CPU 1100, through the chipset 1150. In alternate embodiments, the memory controller 1200 may be integrated into the chipset 1150. The memory controller 1200 may be operably coupled to one or more memory devices 1350. In an embodiment, the memory devices 1350 may include the at least one semiconductor apparatus as discussed above with relation to FIGS. 1-3, the memory devices 1350 may include a plurality of word lines and a plurality of bit lines for defining a plurality of memory cell. The memory devices 1350 may be any one of a number of industry standard memory types, including but not limited to, single inline memory modules (“SIMMs”) and dual inline memory modules (“DIMMs”). Further, the memory devices 1350 may facilitate the safe removal of the external data storage devices by storing both instructions and data.

The chipset 1150 may also be coupled to the I/O bus 1250. The I/O bus 1250 may serve as a communication pathway for signals from the chipset 1150 to I/O devices 1410, 1420 and 1430. The I/O devices 1410, 1420 and 1430 may include a mouse 1410, a video display 1420, or a keyboard 1430. The I/O bus 1250 may employ any one of a number of communications protocols to communicate with the I/O devices 1410, 1420, and 1430. Further, the I/O bus 1250 may be integrated into the chipset 1150.

The disk drive controller 1450 (i.e., internal disk drive) may also be operably coupled to the chipset 1150. The disk drive controller 1450 may serve as the communication pathway between the chipset 1150 and one or more internal disk drives 1450. The internal disk drive 1450 may facilitate disconnection of the external data storage devices by storing both instructions and data. The disk drive controller 1300 and the internal disk drives 1450 may communicate with each other or with the chipset 1150 using virtually any type of communication protocol, including all of those mentioned above with regard to the I/O bus 1250.

It is important to note that the system 1000 described above in relation to FIG. 4 is merely one example of a system employing the semiconductor apparatuses as discussed above with relation to FIGS. 1-3. In alternate embodiments, such as cellular phones or digital cameras, the components may differ from the embodiments illustrated in FIG. 4.

While various embodiments have been described above, it will be understood to those skilled in the art that the embodiments described are by way of example only. Accordingly, the semiconductor apparatus described herein should not be limited based on the described embodiments.

What is claimed is:

1. A semiconductor apparatus comprising:
a first normal circuit configured to generate a normal signal while operating in a normal operation;
a test signal generation unit configured to generate a test signal in response to a test control signal;
a signal transfer unit configured to transfer one of either the normal signal or the test signal, as an internal signal, to a signal line;
a second normal circuit configured to perform the normal operation in response to receiving the internal signal from the signal line; and
a test operation circuit configured to perform a test operation in response to receiving the internal signal from the signal line.

2. The semiconductor apparatus according to claim 1, wherein the test signal generation unit disables the test signal in response to a signal commanding for the normal operation.

3. The semiconductor apparatus according to claim 2, wherein the signal commanding for the normal operation includes an active signal.

4. The semiconductor apparatus according to claim 2,
wherein the test signal generation unit comprises:
a decoding section configured to decode the test control signal, and generate a decoding signal; and
a latch section configured to latch the decoding signal, and output the test signal.

5. The semiconductor apparatus according to claim 4, wherein the latch section disables the test signal in response to receiving the signal commanding for the normal operation.

6. The semiconductor apparatus according to claim 1, wherein the signal transfer unit enables the internal signal when one of either the normal signal or the test signal is enabled, and outputs the enabled internal signal to the signal line.

7. The semiconductor apparatus according to claim 1, wherein the test operation circuit comprises:
a test signal input control unit configured to latch the internal signal received from the signal line, and output a test latch signal; and
a test circuit configured to perform the test operation in response to the test latch signal.

8. The semiconductor apparatus according to claim 7, wherein the test signal input control unit disables the test latch signal in response to a test initialization signal.

9. A semiconductor apparatus comprising:
a first normal circuit configured to generate a first normal signal while operating in a normal operation;
a second normal circuit configured to generate a second normal signal while operating in the normal operation;
a test signal generation unit configured to generate a first test signal and a second test signal in response to a test control signal;
a first signal transfer unit configured to transfer one of either the first normal signal or the first test signal, as a first internal signal, to a first signal line;
a second signal transfer unit configured to transfer one of either the second normal signal or the second test signal, as a second internal signal, to a second signal line;
a third normal circuit configured to perform the normal operation in response to receiving the first internal signal from the first signal line;
a fourth normal circuit configured to perform the normal operation in response to receiving the second internal signal from the second signal line;
a first test operation circuit configured to perform a test operation in response to receiving the first internal signal from the first signal line; and
a second test operation circuit configured to perform the test operation in response to receiving the second internal signal from the second signal line.

10. The semiconductor apparatus according to claim 9, wherein the test signal generation unit disables the first and second test signals in response to a signal commanding for the normal operation.

11. The semiconductor apparatus according to claim 10,
wherein the test signal generation unit comprises:
a decoding section configured to decode the test control signal, and generate a first decoding signal and a second decoding signal;
a first latch section configured to latch the first decoding signal, and output the first test signal; and
a second latch section configured to latch the second decoding signal, and output the second test signal.

12. The semiconductor apparatus according to claim 11,
wherein the first and second latch sections disable the first and second test signals in response to receiving the signal commanding for the normal operation.

13. The semiconductor apparatus according to claim 10, wherein the first and second test operation circuits interrupt performance of the test operation in response to a test initialization signal.

14. A semiconductor apparatus comprising:
a normal circuit;
a signal transfer unit coupled to the normal circuit through a signal line; and
a test operation circuit coupled to the signal line,
wherein the signal transfer unit is configured to output an internal signal to the signal line in response to receiving a test signal or a normal signal.

15. The semiconductor apparatus according to claim 14, further comprising a first normal circuit configured to generate the normal signal while normally operating.

16. The semiconductor apparatus according to claim 14, further comprising a test signal generation unit configured to generate the test signal in response to a test control signal.

17. The semiconductor apparatus according to claim 14, wherein the signal transfer unit includes a NOR gate configured to receive both the normal signal and the test signal, and an inverter for receiving the output of the NOR gate and outputting the internal signal to the signal line.

18. The semiconductor apparatus according to claim 14, wherein the test operation circuit is configured to perform a test operation in response to receiving the internal signal from the signal line.

19. The semiconductor apparatus according to claim 14, wherein the normal circuit is configured to perform a normal operation in response to receiving the internal signal from the signal line.

20. The semiconductor apparatus according to claim 16, wherein the test signal generation unit disables the test signal in response to a signal including a normal operation.

21. A semiconductor apparatus comprising:
a first normal circuit;
a signal transfer unit electrically coupled between the first normal circuit and a signal line; and
a test signal generation unit coupled to the signal transfer unit,
wherein the signal transfer unit is configured to output test signals to the signal line in a test mode, and output normal signals, using the same signal line used by the test signals, while the semiconductor apparatus operates in a normal operation.
